(19) United States
(12) Patent Application Publication
(10) Pub. No.: US 2007/0073499 A1
(43) Pub. Date: Mar. 29, 2007

(54) Method and apparatus for determining one or more s-parameters associated with a device under test (DUT)

(76) Inventors: T. Shannon Sawyer, Fort Collins, CO (US); Minh van Quach, Fort Collins, CO (US)

Correspondence Address: AVAGO TECHNOLOGIES, LTD., P.O. BOX 1920, DENVER, CO, 80201-1920, US

(21) Appl. No.: 11/235,819

(22) Filed: Sep. 27, 2005

(51) Int. Cl. G01R 23/00; G06F 19/00

(52) U.S. Cl. 702/75

(57) ABSTRACT

Frequency domain responses associated, respectively, with a fixture having a DUT connected to it and a fixture without the DUT are converted into respective time-domain responses that are then used to construct respective time-domain circuit models. The time-domain circuit model corresponding to the fixture by itself is subsequently de-embedded from the time-domain circuit model corresponding to the fixture and the DUT connected to it to obtain a time-domain circuit model for the DUT by itself. The time-domain circuit model for the DUT is operated over a range of frequencies as the frequency domain response is measured. The s-parameters for the DUT are then computer from the frequency domain response for the DUT.

### BACKGROUND OF THE INVENTION

Vector network analyzers (VNAs) are often used to measure characteristics of devices under test (DUTs), such as integrated circuits (ICs), to ensure that they are operating properly before being shipped to a customer. A known VNA used for this purpose is the AT-E8362B VNA, which is a 10 megahertz (MHz) to 20 gigahertz (GHz) VNA available from Agilent Technologies. VNAs enable measurement of the forward and reverse gain and phase response of a circuit, as well as input and output reflection properties (i.e., complex impedance) of the circuit. These parameters are commonly referred to as scattering parameters, or s-parameters.

A full VNA has two measurement circuits, namely, one in the forward direction that measures forward gain and phase (s₂₁) and input reflection magnitude and phase (s₁₁), and a duplicate circuit in the reverse direction that measures output reflection magnitude and phase (s₂₂) and reverse gain and phase (s₁₂). Some VNAs only provide sufficient hardware to measure in one direction. In such cases, in order to measure in the other direction, the device under test (DUT) is physically reversed and the measurements are again performed.

FIG. 1 illustrates a block diagram of a known VNA 1 connected at transmit (T_{X}) and receive (R_{X}) terminals 2 and 3 of the VNA 1 to transmit (T_{X}) and receive (R_{X}) terminals 6 and 7 of a circuit board 8 by cables 11 and 12. The cables 11 and 12 are typically coaxial cables, but other types of cables may be used for this purpose as well. The circuit board 8 has an IC 9 mounted to a socket (not shown) of the circuit board 8, and includes various components, such as electrical connectors, discrete components (e.g., capacitors, resistors, inductors), circuit board traces, the socket, etc.

In order to measure the s-parameters associated with the die of the IC 9, the entire path is measured from the T_{X} and R_{X} terminals 6 and 7 of the circuit board 8 through the connectors, circuit board traces, other components of the circuit board 8, and socket, and through the package of the IC to the IC die (not shown). The s-parameters associated with the die of the IC 9 are then determined from the measured frequency response along the entire path. The problem with this technique is that s-parameters for the entire system are more than what is required, and must be filtered out to uncover the s-parameters of only the DUT.

One option to this known technique is to build a custom circuit board for each IC to be tested with special fixtures that attempt to minimize the extraneous responses. However, a custom board must be built for each and every IC to be tested, which is expensive and time consuming, especially when a large number of ICs need to be tested.

Another option is to use a de-embedding technique that computationally strips away the scattering effects caused by everything between the points at which the cables from the VNA connect to the circuit board and the DUT (e.g., the connectors, circuit board traces, the socket, the IC package, etc.). If de-embedding is performed correctly, then only the s-parameters associated with the DUT will be measured. However, such de-embedding techniques are performed in the frequency domain, and it is very difficult when performing de-embedding to ensure that neither too much nor too little is removed. Consequently, it is difficult to ensure that the s-parameters associated with only the DUT are measured.

Accordingly, a need exists for a de-embedding technique that enables s-parameters associated with a DUT to be precisely measured.

### SUMMARY OF THE INVENTION

The invention provides a method, an apparatus, a system, and an encoded computer-readable medium for determining one or more scattering parameters (s-parameters) associated with a device under test (DUT). A processing device of the apparatus processes a frequency domain response relating to a fixture and a DUT connected to the fixture to construct a time-domain circuit model of the fixture and connected DUT. The processing device processes a frequency domain response relating to the fixture by itself to construct a time-domain circuit model of the fixture. The processing device de-embeds the circuit model of the fixture by itself from the circuit model of the fixture and connected DUT to produce a circuit model of the DUT. The processing device operates the DUT circuit model over a range of frequencies and measures a frequency domain response of the DUT circuit model. The processing device processes the frequency domain response of the DUT circuit model to compute one or more s-parameters for the DUT.

The system comprises a computer that receives a file containing first and second frequency domain responses from a VNA in communication with the computer. The first frequency domain response is associated with a fixture and DUT connected to the fixture. The second frequency domain response is associated with only the fixture. The computer converts the respective frequency domain responses into respective time-domain responses, constructs respective circuit models based on the respective time-domain responses, and de-embeds the circuit model of the fixture by itself from the circuit model of the fixture and the connected DUT to obtain a circuit model of the DUT. The DUT circuit model is then operated over a range of frequencies while the corresponding frequency response is measured. The computer then computes the s-parameters for the DUT from the frequency domain response of the DUT.

In accordance with the method, a frequency domain response relating to a fixture and a DUT connected to the fixture is used to construct a time-domain circuit model of the fixture and connected DUT. A frequency domain response relating to the fixture by itself is used to construct a time-domain circuit model of the fixture. The circuit model of the fixture by itself is de-embedded from the circuit model of the fixture and connected DUT to produce a circuit model of the DUT. The DUT circuit model is operated over a range of frequencies while the frequency domain response of the DUT circuit model is measured. The frequency domain response of the DUT circuit model is then used to compute one or more s-parameters for the DUT.

A computer-readable medium comprises code for receiving as input in a computer one or more files from a vector network analyzer (VNA) that contain a frequency domain response associated with the fixture and connected DUT and a frequency domain response associated with the fixture by itself, code for converting the respective frequency domain responses contained in the files into respective time-domain responses, code for constructing respective time-domain circuit models based on the respective time-domain responses, code for de-embedding the time-domain circuit model corresponding to the fixture by itself from the time-domain circuit model corresponding to the fixture and the connected DUT to produce a time-domain circuit model of the DUT, code for operating the time-domain circuit model of the DUT over a range of frequencies while measuring a frequency domain response for the DUT, and code for computing s-parameters for the DUT based on the DUT frequency domain response.

These and other features and advantages of the invention will become apparent from the following description, drawings and claims.

### BRIEF DESCRIPTION OF THE DRAWINGS

FIG. 1 illustrates a block diagram of a known VNA connected at transmit (T_{X}) and receive (R_{X}) terminals and of the VNA I to transmit (T_{X}) and receive (R_{X}) terminals and of a circuit board by cables.

FIG. 2A illustrates the corresponding frequency response plot for the entire signal path (i.e., fixture+DUT).

FIG. 2B illustrates the corresponding frequency response plot for the signal path for only the fixture.

FIG. 3A illustrates a time domain plot 41 that corresponds to a conversion of the frequency domain plot 11 shown in FIG. 2A from the frequency domain to the time domain.

FIG. 3B illustrates a time domain plot 43 that corresponds to a conversion of the frequency domain plot 13 shown in FIG. 2A from the frequency domain to the time domain.

FIGS. 4A and 4B illustrate a flowchart that represents the method of the invention in accordance with the preferred embodiment.

FIG. 5 illustrates a block diagram of the system of the invention in accordance with the preferred embodiment.

### DETAILED DESCRIPTION OF THE PREFERRED EMBODIMENT

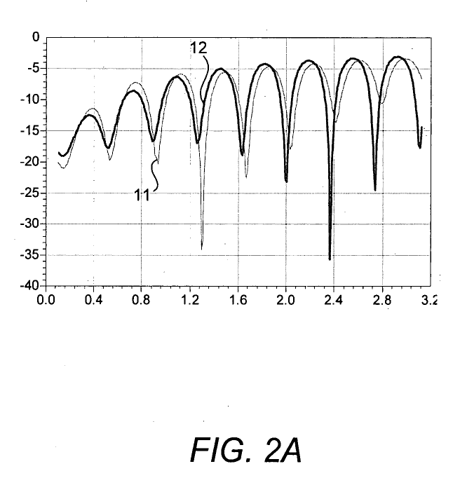

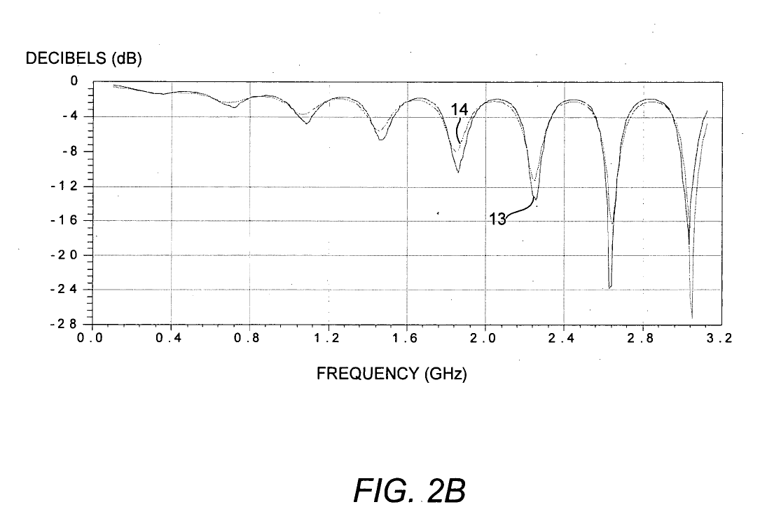

In accordance with the invention, a method and an apparatus are provided which ensure that the s-parameters associated with the DUT (e.g., the IC die itself) are precisely measured. The manner in which this is accomplished in accordance with an exemplary embodiment will now be described with reference to FIGS. 2A-4B.

Using a known VNA, such as the aforementioned AT-E8362B VNA, the s-parameters are measured in the known fashion for the signal path including the fixture and the DUT (fixture+DUT). The term “fixture”, as that term is used herein, is intended to denote all of the features and components in the signal path between the points where the VNA cables connect to the circuit board on which the DUT is mounted, and the DUT. Thus, the fixture will typically include, for example, connectors, circuit board traces, discrete components along the signal path (e.g., resistors, capacitors, inductors, etc.), and the socket in which the DUT is mounted. The DUT will typically be the die itself, in which case the invention enables the s-parameters associated with only the die to be precisely measured. The VNA is calibrated in such a manner that the cables that connect the circuit board to the VNA have no effect on the measurements. Persons skilled in the art understand the manner in which such calibration is performed.

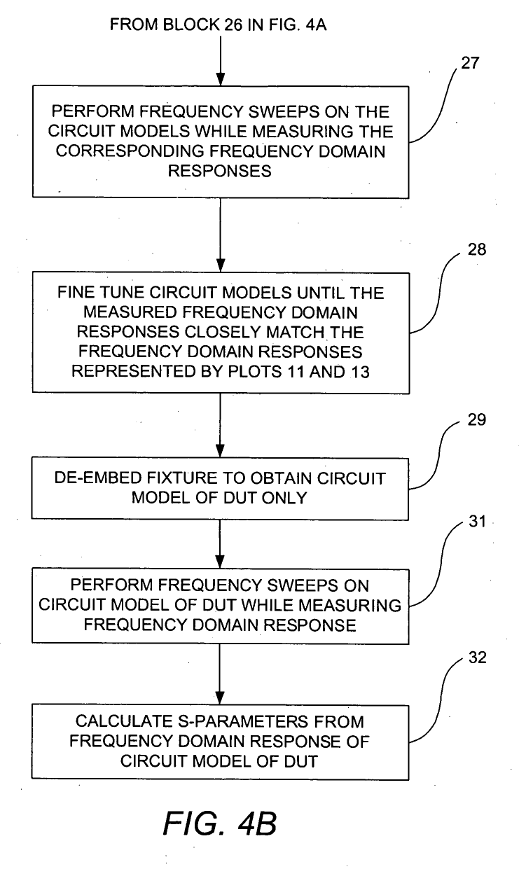

FIG. 2A illustrates the corresponding frequency response plot for the entire signal path (i.e., fixture+DUT). The horizontal axis represents frequency in Gigahertz (GHz) and the vertical axis represents gain in decibels (dB). FIG. 2A actually illustrates two frequency response plots 11 and 12. Plot 11 corresponds to the frequency response measured by the VNA for the fixture-plus-DUT signal path. Plot 12 corresponds to a frequency response plot that is based on a simulation, which will be described below in detail with reference to the flow charts illustrated in FIGS. 4A and 4B. From the frequency response plot 11, the VNA calculates the s-parameters in the typical manner. This step of measuring the frequency response and calculating the corresponding s-parameters for the entire signal path (i.e., fixture+DUT) is represented by block 21 of the flow chart illustrated in FIG. 4A.

In a similar manner, the s-parameters are measured in the known fashion using a VNA for the signal path that includes the fixture, but not the DUT. In this case, the DUT is removed from the socket and the fixture is terminated. FIG. 2B illustrates the corresponding frequency response plot 13 for this signal path as measured by the VNA. The horizontal axis in FIG. 2B represents frequency in GHz and the vertical axis represents gain in dB. FIG. 2B also illustrates a second frequency response plot 14, which is based on a simulation, as will be described below in detail with reference to the flow charts illustrated in FIGS. 4A and 4B.

From the frequency response plot 13, the VNA calculates the s-parameters for the signal path that includes the fixture, but not the DUT. This step of measuring the frequency response for the fixture and calculating the corresponding s-parameters is represented by block 22 in the flow chart illustrated in FIG. 4A.

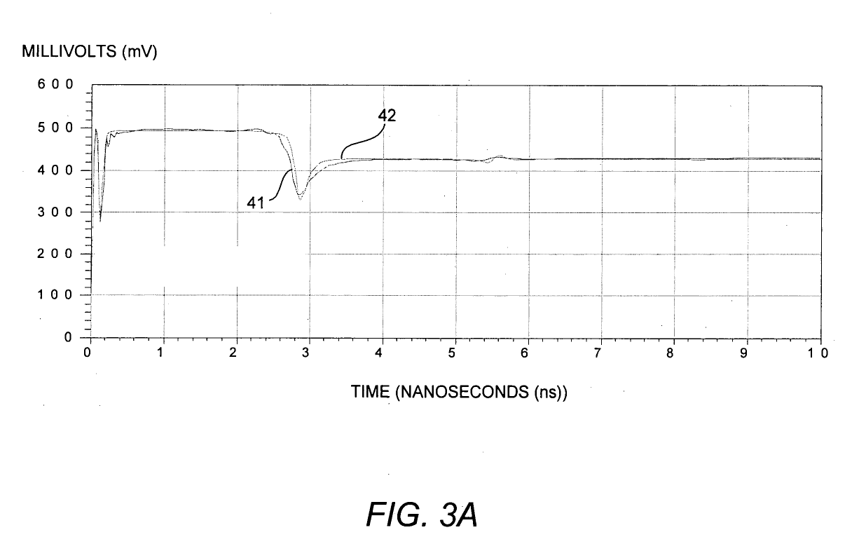

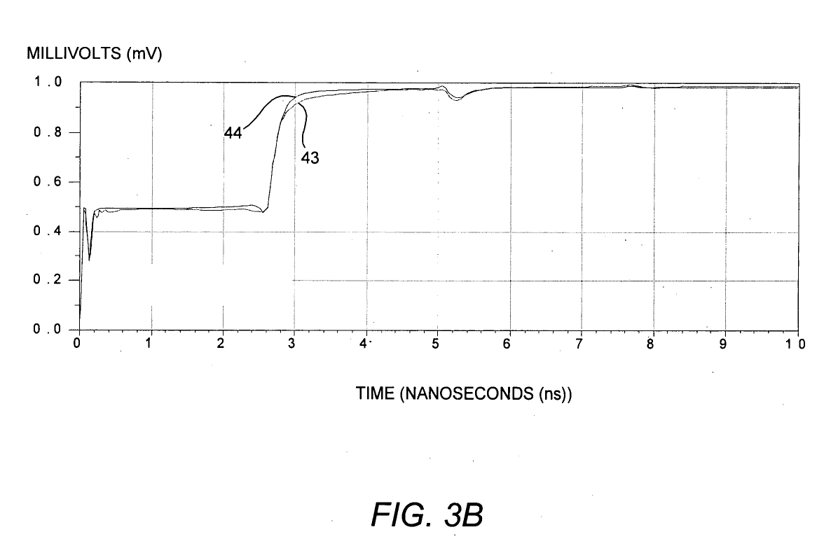

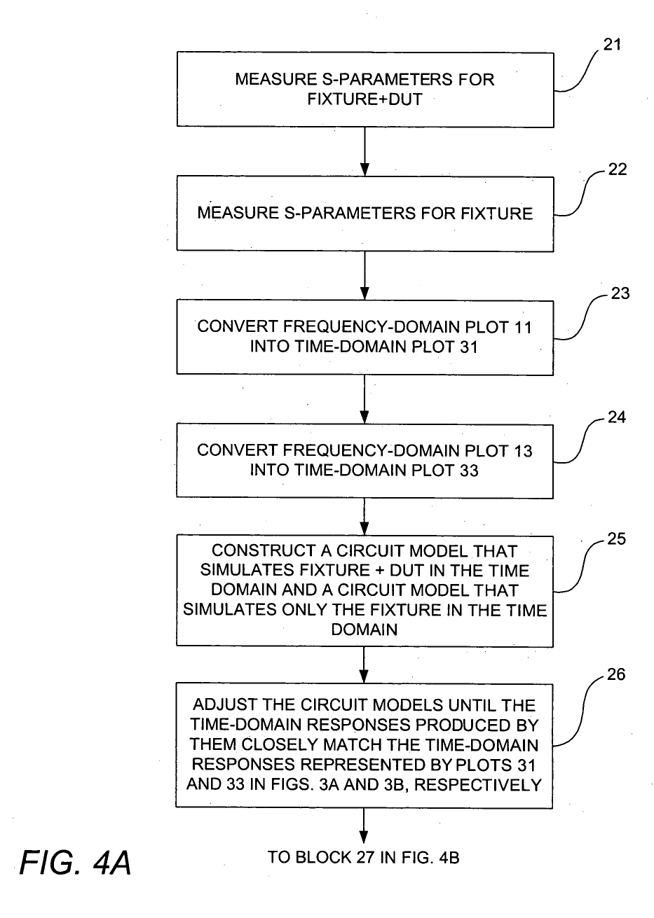

FIG. 3A illustrates a time domain plot 41 that corresponds to a conversion of the frequency domain plot 11 shown in FIG. 2A from the frequency domain to the time domain. The horizontal axis represents time in nanoseconds and the vertical axis represents voltage in millivolts. The conversion is performed in a straight-forward manner using a suitable Fourier Transform, such as the well-known Fast Fourier Transform (FFT). The conversion of plot 11 from the frequency domain into the time domain to produce time-domain plot 41 is represented by block 23 in FIG. 4.

FIG. 3A also illustrates a simulated time-domain plot 42. The manner in which the simulated time-domain plot 42 is produced is described below with reference to the flow charts illustrated in FIGS. 4A and 4B.

FIG. 3B illustrates a time domain plot 43 that corresponds to a conversion of the frequency domain plot 13 shown in FIG. 2A from the frequency domain to the time domain. The conversion is performed in the same way as described above with reference to FIG. 3A, i.e., using a suitable Fourier Transform, such as the FFT. The conversion of plot 13 shown in FIG. 2B from the frequency domain into the time domain to produce time-domain plot 43 shown in FIG. 3B is represented by block 24 in FIG. 4A.

FIG. 3B also illustrates a simulated time-domain plot 44. The manner in which the simulated time-domain plot 44 is produced is described below with reference to the flow charts illustrated in FIGS. 4A and 4B.

Once the time-domain plots 41 and 43 have been obtained, circuit models are constructed in software that are intended to simulate the time-domain responses represented plots 41 and 43. Typically, this will be accomplished by using a known radio frequency (RF) circuit simulator. One circuit model will simulate the fixture plus the DUT, and will be intended to produce a time-domain response that closely matches the time-domain response plot 41 shown in FIG. 3A. The other circuit model will simulate only the fixture, and will be intended to produce a time-domain response that closely matches the time-domain response represented by plot 43 shown in FIG. 3B. The steps of constructing these circuit models are collectively represented by block 25 in FIG. 4A.

Once the circuit models have been constructed, they are adjusted until the respective time-domain responses produced by them closely match the respective time-domain responses represented by plots 41 and 43. The time-domain response plot 42 (FIG. 3A) is the time-domain response plot that is produced by simulating the circuit model of the fixture plus the DUT and by adjusting the circuit model until its time-domain response closely matches the time-domain response represented by plot 41 (FIG. 3A). Similarly, the time-domain plot 44 (FIG. 3B) is the time-domain response produced by simulating the circuit model of the fixture without the DUT and adjusting the circuit model until its time-domain response closely matches the time-domain response represented by plot 43 (FIG. 3B). The steps of simulating the circuit models, measuring the time-domain responses, and adjusting the circuit models to achieve time-domain responses that closely match the time-domain responses represented by plots 41 and 43 are collectively represented in FIG. 4A by block 26.

Once the circuit models have been properly adjusted, they should be fine tuned to ensure that they are accurate. In other words, the circuit models should be validated. This is accomplished by performing frequency sweeps on the circuit models while measuring the corresponding frequency domain responses, and by fine tuning the circuit models until their frequency domain responses closely match the frequency domain responses represented by plots 11 and 13 shown in FIGS. 2A and 2B, respectively. These steps are represented by blocks 27 and 28 shown in FIG. 4B. Plot 12 shown in FIG. 2A corresponds to the frequency domain response obtained by fine-tuning the circuit model that represents the fixture+DUT. Plot 14 shown in FIG. 2B corresponds to the frequency domain response obtained by fine-tuning the circuit model that represents the fixture without the DUT.

Now that the accuracy of the models has been validated, the circuit model representing only the fixture is subtracted from the circuit model representing the fixture+DUT. In other words, the fixture is de-embedded, as indicated by block 29. The result is a circuit model that accurately represents only the DUT. Frequency sweeps are then performed on the circuit model that represents only the DUT and the corresponding frequency domain response is measured, as indicated by block 31. The corresponding s-parameters for the DUT are then calculated from the measured frequency domain response, as indicated by block 32.

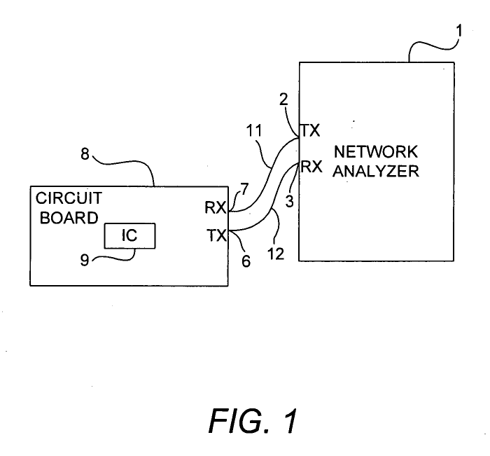

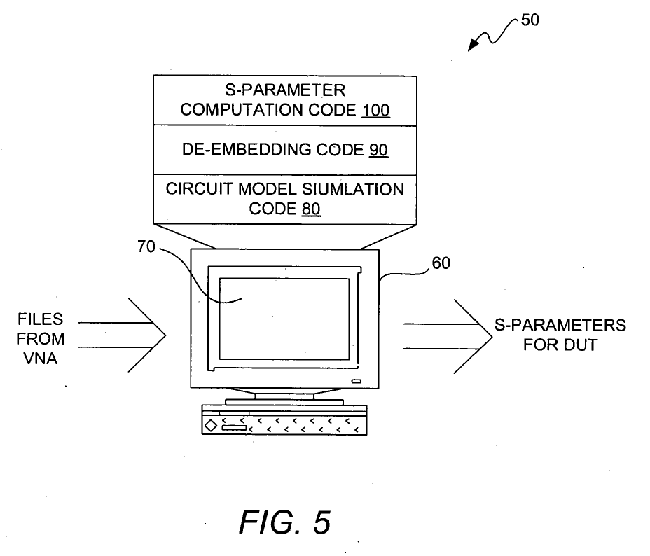

FIG. 5 illustrates a block diagram of the system 50 of the invention in accordance with an embodiment. The system 50 preferably includes a computer 60 that is coupled to a VNA, such as the VNA 1 shown in FIG. 1, for receiving the frequency domain information computed by the VNA. The computer 60 may include a display monitor 70 for displaying information to a user, such as the plots shown in FIGS. 2A-4B. The computer 60 preferably is programmed with code 80 for performing the circuit model simulation, adjustment and fine-tuning, code 90 for performing the de-embedding of the fixture, and code 100 for performing the s-parameter computations associated with the DUT. Thus, the output of the system 50 is the s-parameters associated with the DUT, which may be displayed, printed or otherwise made available to the user of the system 50.

Although the invention has been described with reference to FIG. 5 as being performed in software being executed by a computer, the invention may instead be performed in hardware, or in a combination of hardware and software. The term “processing device” will be used herein to denote any such implementations. For example, the processing device may be one or more microprocessors programmed with software to perform the functions of the invention, or it may be a combination of logic gates configured to perform the functions of the invention. Also, the processing device of the invention may be a single computational device or multiple computational devices, such as multiple processors or computers distributed over a network.

It should be noted that it is not necessary for the computer 60 to construct and simulate the time-domain circuit models. A separate computer (not shown) may receive the files from the VNA, construct the circuit models using the information contained in the files, and perform simulations with the circuit models and make any necessary adjustments. The adjusted circuit models would then be delivered to computer 60 for de-embedding and s-parameter computation.

Although the invention has been described with reference to computing all of the s-parameters, in some cases it may be desirable to computer only one or a few of the s-parameters, such as the return loss and/or insertion loss parameters. A serializer/deserializer (serDes) device is a device that receives parallel data and converts it into a serial stream of data for transmission over a serial link. At the other end, a SerDes device converts the serial data back into parallel data. A SerDes device typically includes an application specific integrated circuit (ASIC) that performs these conversions and other functions. The invention is capable of very precisely measuring the return loss and insertion loss s-parameters for SerDes ASICs.

It should be noted that the invention has been described with reference to preferred and exemplary embodiments, and that the invention is not limited to the embodiments explicitly described herein. For example, the flowcharts shown in FIGS. 4A and 4B demonstrate the performance of particular steps in a particular order. Modifications can be made to the steps themselves and to the order in which they are performed, and all such modifications are within the scope of the invention.

Also, some of the steps shown may not be necessary in all cases. For example, the steps represented by blocks 26-28 correspond to portions of the algorithm that are performed to ensure that the algorithm is performed in a fashion that ensures robustness and precision. However, one or more of these steps may be deleted altogether, while still obtaining a desired degree of accuracy and precision. For example, the steps of adjusting, fine-tuning and validating the time-domain circuit models (blocks 26, 27 and 28) may not need to be performed if it is reasonably certain that the circuit models constructed during the step represented by block 25 are accurate. These and other modifications may be made to the embodiments described herein, and all such modifications are within the scope of the invention.

What is claimed is:

1. An apparatus for determining one or more scattering parameters (s-parameters) associated with a device under test (DUT), the apparatus comprising:
a processing device configured to:
process a frequency domain response relating to a fixture and a DUT connected to the fixture to construct a time-domain circuit model of the fixture and connected DUT;
process a frequency domain response relating to the fixture by itself to construct a time-domain circuit model of the fixture;
de-embed the circuit model of the fixture by itself from the circuit model of the fixture and connected DUT to produce a circuit model of the DUT;
operate the DUT circuit model over a range of frequencies and to measure a frequency domain response of the DUT circuit model; and
process the frequency domain response of the DUT circuit model to compute one or more s-parameters for the DUT.

2. The apparatus of claim 1, wherein the processing device is further configured to:
simulate operations of the circuit models in the time domain and, if necessary, to adjust the circuit models to ensure that the circuit models accurately represent the fixture and connected DUT and the fixture by itself, respectively, the simulations being performed prior to the processing device performing the de-embedding, and wherein de-embedding is performed using the circuit models as adjusted by any necessary adjustments.

3. The apparatus of claim 1, wherein the processing device is further configured to:
frequency sweep the circuit models prior to de-embedding and measuring respective frequency domain responses associated with the respective circuit models during the frequency sweep; and
fine-tune the respective circuit models during the frequency sweep to ensure that the respective frequency domain responses measured during the frequency sweep closely match the frequency domain responses that were processed to construct the circuit models.

4. The apparatus of claim 1, wherein the processing device is further configured to:
simulate operations of the circuit models in the time domain and, if necessary, to adjust the circuit models to ensure that the circuit models accurately represent the fixture and connected DUT and the fixture by itself, respectively, the simulations being performed prior to the processing device performing the de-embedding, and wherein the processing device performs de-embedding using the circuit models as adjusted by any necessary adjustments.
frequency sweep the circuit models prior to de-embedding and to measure respective frequency domain responses associated with the respective circuit models during the frequency sweep; and
fine-tune the respective circuit models during the frequency sweep to ensure that the respective frequency domain responses measured during the frequency sweep closely match the frequency domain responses that were processed to construct the circuit models.

5. The apparatus of claim 1, wherein the apparatus is a computer programmed with software, the computer receiving as input one or more files from a vector network analyzer (VNA), the files containing a frequency domain response associated with the fixture and connected DUT and a frequency domain response associated with the fixture by itself, the first and second logic using the respective frequency domain responses contained in the files to construct the respective time-domain circuit models.

6. A system for performing de-embedding, the system comprising:
a computer that receives a file containing first and second frequency domain responses from a vector network analyzer (VNA) in communication with the computer, the first frequency domain response being associated with a fixture and a device under test (DUT) connected to the fixture, the second frequency domain response being associated with only the fixture, the computer converting the respective frequency domain responses into respective time-domain responses, constructing respective circuit models based on the respective time-domain responses, and de-embedding the circuit model of the fixture by itself from the circuit model of the fixture and the connected DUT to obtain a circuit model of the DUT.

7. A method for determining one or more scattering parameters (s-parameters) associated with a device under test (DUT), the method comprising:
using a frequency domain response relating to a fixture and a DUT connected to the fixture to construct a time-domain circuit model of the fixture and connected DUT;
using a frequency domain response relating to the fixture by itself to construct a time-domain circuit model of the fixture;
de-embedding the circuit model of the fixture by itself from the circuit model of the fixture and connected DUT to produce a circuit model of the DUT;
operating the DUT circuit model over a range of frequencies while measuring a frequency domain response of the DUT circuit model; and
using the frequency domain response of the DUT circuit model to compute one or more s-parameters for the DUT.

8. The method of claim 7, further comprising:
prior to de-embedding, simulating operations of the circuit models in the time domain and, if necessary, to adjusting the circuit models to ensure that the circuit models accurately represent the fixture and connected DUT and the fixture by itself, respectively, and wherein the de-embedding step is performed using the circuit models as adjusted by any necessary adjustments.

9. The method of claim 8, further comprising:
after any necessary adjustments have been made to the circuit models, and prior to de-embedding, operating the circuit models over a range of frequencies and measuring respective frequency domain responses associated with the respective circuit models, and fine-tuning the respective circuit models as the circuit models are operated over the frequency range to ensure that the respective frequency domain responses measured during operation of the circuit models over the frequency range closely match the frequency domain responses that were used to construct the circuit models.

10. A method for determining one or more scattering parameters (s-parameters) associated with a device under test (DUT), the method comprising:
receiving as input in a computer one or more files from a vector network analyzer (VNA), the files containing a frequency domain response associated with the fixture and connected DUT and a frequency domain response associated with the fixture by itself;
converting the respective frequency domain responses contained in the files into respective time-domain responses;
constructing respective time-domain circuit models based on the respective time-domain responses;
de-embedding the time-domain circuit model corresponding to the fixture by itself from the time-domain circuit model corresponding to the fixture and the connected DUT to produce a time-domain circuit model of the DUT;
operating the time-domain circuit model of the DUT over a range of frequencies while measuring a frequency domain response for the DUT; and
computing s-parameters for the DUT based on the DUT frequency domain response.

11. A method for performing de-embedding, the method comprising:
receiving as input in a computer one or more files from a vector network analyzer (VNA), the files containing a frequency domain response associated with the fixture and connected DUT and a frequency domain response associated with the fixture by itself;
converting the respective frequency domain responses contained in the files into respective time-domain responses;
constructing respective time-domain circuit models based on the respective time-domain responses; and
de-embedding the time-domain circuit model corresponding to the fixture by itself from the time-domain circuit model corresponding to the fixture and the connected DUT to produce a time-domain circuit model of the DUT.

12. A computer program for determining one or more scattering parameters (s-parameters) associated with a device under test (DUT), the computer program being embodied on a computer-readable medium, the program comprising:
a first code segment for receiving as input in a computer one or more files from a vector network analyzer (VNA), the files containing a frequency domain response associated with the fixture and connected DUT and a frequency domain response associated with the fixture by itself;
a second code segment for converting the respective frequency domain responses contained in the files into respective time-domain responses;
a third code segment for constructing respective time-domain circuit models based on the respective time-domain responses;
a fourth code segment for de-embedding the time-domain circuit model corresponding to the fixture by itself from the time-domain circuit model corresponding to the fixture and the connected DUT to produce a time-domain circuit model of the DUT;
a fifth code segment for operating the time-domain circuit model of the DUT over a range of frequencies while measuring a frequency domain response for the DUT; and
a sixth code segment for computing s-parameters for the DUT based on the DUT frequency domain response.
